(19) United States
(12) Patent Application Publication
(10) Pub. No.: US 2011/0111602 A1
(43) Pub. Date: May 12, 2011

(54) PLASMA PROCESSING METHOD

(75) Inventors: Makoto SUYAMA, Yanai (JP); Takeshi Shimada, Hikari (JP); Atsushi Yoshida, Kudamatsu (JP); Yasukiyo Morioka, Kudamatsu (JP); Kota Tanaka, Shunan (JP)

(73) Assignee: Hitachi High-Technologies Corporation

(21) Appl. No.: 12/694,386

(22) Filed: Jan. 27, 2010

(30) Foreign Application Priority Data
Nov. 6, 2009 (JP) 2009-254855

(51) Int. Cl. H01L 21/3065

(52) U.S. Cl. 438/719; 257/E21.218

(57) ABSTRACT

Disclosed is a plasma processing method that excels in mass production consistency as it suppresses the flaking of a reaction product deposited on a portion outside the effective range of a Faraday shield in a vacuum vessel. The plasma processing method, which plasma-processes a sample having a layer made of an etch-resistant material by using a plasma processing apparatus having a discharger and a processor, includes a first step of performing an aging process that is to be performed before etching the sample, a second step of performing etching by plasma-processing the layer that is made of an etch-resistant material and formed on the sample, a third step of stabilizing a film deposited on the inner wall of a chamber forming the processor by performing plasma processing after the second step, and an additional step of repeating the second step and the third step.

### CLAIM OF PRIORITY

The present application claims priority from Japanese Patent Application JP 2009-254855 filed on Nov. 6, 2009, the content of which is hereby incorporated by reference into this application.

### BACKGROUND OF THE INVENTION

(1) Field of the Invention

The present invention relates to a plasma processing method, and more particularly to a plasma processing method suitable for etching an etch-resistant material in a vacuum processing vessel.

(2) Description of the Related Art

In recent years, materials to be etched in the field of manufacturing semiconductor devices such as a DRAM (Dynamic Random Access Memory) and a logic circuit IC are relatively etch-resistant materials such as Si, Al, and SiO₂. Further, Fe and other similar etch-resistant materials are used for FRAMs (Ferroelectric Random Access Memories), MRAMs (Magnetoresistive Random Access Memories), magnetic heads, and the like.

More specifically, the etch-resistant materials include Fe, NiFe, PtMn, and IrMn, which are ferromagnetic or antiferromagnetic and used for MRAMs, magnetic heads, and the like. The etch-resistant materials also include Pt, Ir, Au, Ta, Ru, and other precious metals, which are used in a capacitor or gate section of DRAMs, a capacitor section of FRAMs, or a TMR (Tunneling Magneto-Resistive) element of MRAMs. Further, the etch-resistant materials include high dielectric materials such as Al₂O₃ (aluminum oxide), HfO₃ (hafnium oxide), and Ta₂O₃ (tantalum oxide), and ferroelectric materials such as PZT (lead zirconate titanate), PLZT (lead lanthanum zirconate titanate), BST (barium strontium titanate), and SBT (strontium bismuth tantalate).

These etch-resistant materials are difficult to etch due to a low vapor pressure of a reaction product generated during etching. In addition, a large amount of the reaction product remains deposited on the inner wall of a vacuum vessel after etching. Therefore, when several to several hundred samples are processed, the inner wall of the vacuum vessel is covered with the deposited reaction product. Further, if an excessive amount of the reaction product is deposited, it flakes off the surface of the inner wall and attaches to a wafer as foreign matter. As regards FRAMs and MRAMs, in particular, it is critically important to reduce the amount of foreign matter, which decreases the yield, and stabilize etching characteristics as the elements of devices are miniaturized due to the increasingly high integration of the devices.

Disclosed, for instance, in Japanese Patent Application Laid-Open Publication No. 2000-323298 is a plasma processing apparatus that incorporates a technology for reducing the amount of reaction product deposition on the inner wall of a vacuum vessel during the etching of an etch-resistant material. This plasma processing apparatus generates plasma in a processing vessel by an induction method, has a Faraday shield between the plasma and an inductive antenna mounted on the outer circumference of the vacuum vessel, and reduces the amount of reaction product deposition on the inner wall of the vacuum vessel by connecting a high-frequency power supply to the Faraday shield and supplying electrical power to the Faraday shield or makes the inner wall of the vacuum vessel cleanable. Also disclosed in Japanese Patent Application Laid-Open Publication No. 2003-243362 is a processing method that applies a voltage of 500 V or higher to a Faraday shield and generates plasma with a mixed gas containing boron trichloride (20%) and chlorine (80%) to perform cleaning with high efficiency.

The above-described related arts are merely effective for a portion of the vacuum vessel that is formed with a nonconductive material such as ceramic or quartz and adequately reached by an electric field provided by the Faraday shield (particularly the inner wall of a bell jar serving as a reaction gas discharger). However, a portion formed with the other nonconductive materials or a conductive material (particularly the inner wall of a chamber serving as a sample processor) is not subjected to adequate reaction product deposition control or removal.

A method disclosed in Japanese Patent Application Laid-Open Publication No. 2007-158373 provides component parts with surface irregularities to suppress the deposition and flaking of a reaction product on a portion outside the effective range of a Faraday shield (particularly the inner wall of a chamber serving as a sample processor).

A cleaning method disclosed in Japanese Patent Application Laid-Open Publication No. 2006-237432 cleans an etching apparatus that etches a metal film made, for instance, of Au (gold) or Pt (platinum) with a photoresist used as a masking material. This method provides reproducibility of etching performance by efficiently removing a substance deposited on the inner wall of a vacuum vessel, and continuously minimizes the generation of powdery foreign matter from the inside of the vacuum vessel.

### SUMMARY OF THE INVENTION

As described above, a limit is imposed on the effective range of the plasma processing apparatus that is capable of cleaning the inner wall of the vacuum vessel or reducing the amount of reaction product deposition on the inner wall of the vacuum vessel when a high-frequency power supply is connected to the Faraday field between the inductive antenna and plasma to supply electrical power. The effective range is limited because the plasma processing apparatus merely works on a portion that is formed with a nonconductive substance and adequately reached by an electric field.

When the above processing apparatus etches an etch-resistant material, a portion where the Faraday shield is effective is subjected to reaction product deposition control and removal. However, the reaction product cannot be fully removed from a portion where the Faraday shield is ineffective. There is no problem as far as the deposited reaction product can be removed with relative ease when a plasma cleaning procedure is performed by using a mixed gas containing boron trichloride (BCl₃) and chlorine (Cl₂). However, the deposited reaction product cannot be easily removed when Ir, Pb, or other etch-resistant material is used. As such being the case, a method of preventing the deposited reaction product from readily flaking away from a portion outside the effective range of the Faraday shield by changing the surface roughness of each component part has been employed. However, neither of the above-described methods can successively process more than approximately 100 to 300 samples. No adequate studies have been conducted on the successive processing of approximately 1000 samples.

The present invention has been made in view of the above circumstances and provides a plasma processing method that excels in mass production consistency as it suppresses the flaking of a reaction product deposited on a portion outside the effective range of the Faraday shield in the vacuum vessel (particularly the inner wall of the chamber).

According to one aspect of the present invention, there is provided a plasma processing method including: a plasma processing step of processing a sample having a thin film formed with an etch-resistant material within a chamber; and a stabilization step of stabilizing a film that is deposited on the inner wall of the chamber during the plasma processing step.

According to another aspect of the present invention, there is provided a plasma processing method that processes a sample having a layer of an etch-resistant material by using a plasma processing apparatus having a discharger and a processor, the plasma processing method including: a first step of performing an aging process before etching the sample; a second step of performing etching by plasma-processing the layer of an etch-resistant material formed on the sample; a third step of stabilizing a reaction product deposited on the inner wall of a chamber forming the processor after the second step; and an additional step of repeating the second step and the third step.

The use of the above-described configuration makes it possible to provide a plasma processing method that excels in mass production consistency as it suppresses the flaking of a reaction product deposited on a portion outside the effective range of a Faraday shield in a vacuum vessel (particularly the inner wall of a chamber).

### BRIEF DESCRIPTION OF THE DRAWINGS

Embodiments of the present invention will be described in detail based on the following figures, wherein:

FIG. 1 is a schematic cross-sectional view illustrating a plasma etching apparatus according to a first embodiment of the present invention;

FIG. 2 is a diagram illustrating the configuration of the plasma etching apparatus according to the first embodiment;

FIG. 3 is a schematic cross-sectional view illustrating a sample for use with the first embodiment;

FIG. 4 is a flowchart illustrating a sample processing operation (successive processing operation) performed in accordance with the first embodiment;

FIG. 5 is a diagram illustrating the number of pieces of foreign matter that increased and decreased when successive processing was evaluated;

FIG. 6A is a diagram illustrating the status of a reaction product in a plasma etching apparatus operated by a related art method; and

FIG. 6B is a diagram illustrating the status of a reaction product in the plasma etching apparatus according to the first embodiment.

### DETAILED DESCRIPTION OF THE INVENTION

The following configuration is employed to address the above-described problems. There is provided a plasma processing method for use with a plasma processing apparatus. The plasma processing apparatus includes a discharger, which forms a part of a vacuum processing room, includes a gas ring having a process gas outlet, and is covered with a bell jar cladding the top of the gas ring; a processor, which forms another part of the vacuum processing room and includes a mount that supports a sample and is enclosed by a chamber; an antenna, which is positioned above the bell jar to supply a high-frequency electric field into the vacuum processing chamber and generate plasma; a Faraday shield, which is positioned between the antenna and bell jar to receive the application of a high-frequency bias voltage; and a thermal insulation ring, which is removably attached to the inner surface of the gas ring except for the process gas outlet. Further, the plasma processing apparatus is set for at least about a half of the area of the inner surface of the gas ring including the thermal insulation ring visible from the sample. The plasma processing method processes a laminated film sample made of an etch-resistant material, then replaces it with a Si wafer, and generates plasma of a mixed gas containing boron trichloride (BCl₃) and chlorine (Cl₂).

When the plasma is to be generated, a wafer bias is applied to the Faraday shield, which is positioned between an inductive antenna and plasma, and the Si wafer, which is mounted on an electrode for high-frequency bias application. More specifically, a method of suppressing the flaking of a reaction product deposited on a portion outside the effective range of the Faraday shield in a vacuum vessel (particularly the side wall of the chamber), which is used in the above-described configuration, processes the laminated film sample made of an etch-resistant material, replaces the processed sample with a Si wafer, which is a dummy substrate, after the processing of each sample, and performs plasma processing with mixed gas plasma containing 20 to 40 percent boron trichloride (BCl₃) and 50 to 80 percent chlorine (Cl₂) to etch the Si wafer, which is a dummy substrate, with bias high-frequency power set so as to provide a process pressure of 0.5 to 2.0 Pa, a Faraday shield voltage of 600 to 1500 V (a voltage capable of removing deposits on the inner surface of the bell jar), and a wafer bias voltage of 300 V or higher.

After the processing of each laminated film sample made of an etch-resistant material, the above-described method replaces the processed sample with a Si wafer, which is a dummy substrate, and stabilizes the reaction product by performing processing with the mixed gas plasma containing boron trichloride (BCl₃) and chlorine (Cl₂). Therefore, even when a large number of semiconductor devices are processed, it is possible to suppress the flaking of a reaction product deposited on the inner wall of a vacuum processing vessel, or more specifically, keep the vacuum processing vessel from generating a significant amount of powdery foreign matter.

Embodiments of the present invention will now be described in detail.

### First Embodiment

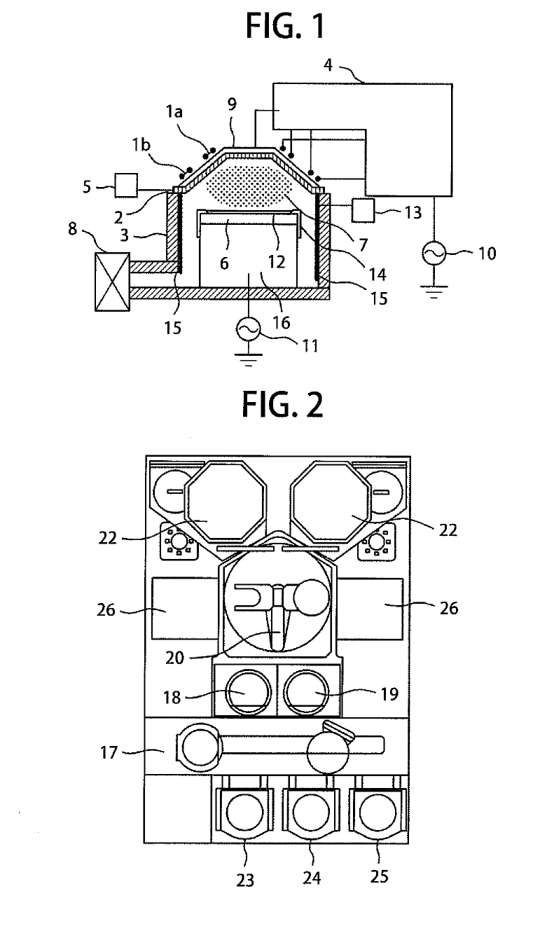

A first embodiment of the present invention will now be described with reference to FIGS. 1 to 5,6A and 6B. FIG. 1 is a schematic cross-sectional view illustrating a vacuum processing apparatus according to the first embodiment. The present embodiment assumes that a plasma etching apparatus is used as the vacuum processing apparatus.

The plasma etching apparatus is a processing apparatus for etching various thin films formed on a semiconductor substrate. It receives the supply of a plasma formation gas, generates plasma, and etches a metallic film or other thin film formed on the substrate.

In the plasma processing apparatus shown in FIG. 1, a processing room, which is enclosed by a bell jar and a chamber, includes a discharger 2, which is covered with the bell jar and made of a nonconductive ceramic material to form a plasma generation section; and a processor 3, which is enclosed by the chamber and provided with a sample 12 to be processed and an electrode 6 for high-frequency bias application. The processor 3 is connected to a ground. The electrode 6 is mounted in the processor 3 via an insulation material. The discharger 2 includes, for instance, inductively-coupled antennas 1a, 1b, a matching box 4, and a first high-frequency power supply 10 for plasma generation purposes. The etching apparatus employed in the present embodiment is configured so that the coiled inductively-coupled antennas 1a, 1b are mounted on the outer circumference of the discharger 2.

A gas supply unit 5 supplies a process gas to the interior of the processing room. In addition, an air exhaust unit 8 evacuates the interior of the processing room to reduce its pressure to a predetermined level. The gas supply unit 5 supplies the process gas to the interior of the processing room so that the process gas is turned into plasma by the action of an electric field generated by the inductively-coupled antennas 1a, 1b. Further, a second high-frequency power supply 11 applies a bias voltage to the electrode 6 in order to bring ions existing in the plasma 7 into the sample 12.

A light emission monitoring unit 13 monitors changes in the intensity of light emitted from an etching gas or a reaction product and locates the end point of an etching material for the sample 12.

The apparatus is structured so as to etch an etch-resistant material. It can suppress the deposition of a reaction product on the discharger 2 and remove a reaction product deposited on the discharger 2 by applying a voltage to a Faraday shield 9. The surface of an inner cover 15, which is installed inside the processor 3, and the surface of an electrode cover 16, which covers the electrode 6, are roughened to prevent a deposited reaction product from flaking off.

The back surface of a susceptor 14 for mounting the sample 12 on the electrode 6 is sprayed with metal so that the plasma 7 applies a voltage to suppress the deposition of a reaction product on the front surface of the susceptor 14 and remove a reaction product deposited on the front surface of the susceptor 14.

FIG. 2 is a schematic plan view illustrating the plasma processing apparatus, which includes a sample transport system. An atmospheric loader 17 is coupled to a load lock room 18 and an unload lock room 19. The load lock room 18 and the unload lock room 19 are coupled to a vacuum transport room 21. The vacuum transport room 21 is coupled to an etching process room 22 and an ashing process room 26.

The sample 12 is transported by the atmospheric loader 17 and a vacuum transport robot 20, etched in the etching process room 22. Further, an in-line process is performed to ash the sample 12 in the ashing process room 26. There are cassette 1 (23), cassette 2 (24), and cassette 3 (25) in the atmospheric loader 17. The sample 12 is to be placed in cassette 1 (23) and cassette 2 (24). A dummy substrate wafer is to be placed in cassette 3 (25). As the cassette dedicated to a dummy is provided, there is no need to replace a sample 12 in a cassette with a dummy substrate wafer. The sample 12 placed in a cassette for a sample is transported as needed to the etching process room 22, etched, and then returned to the same cassette.

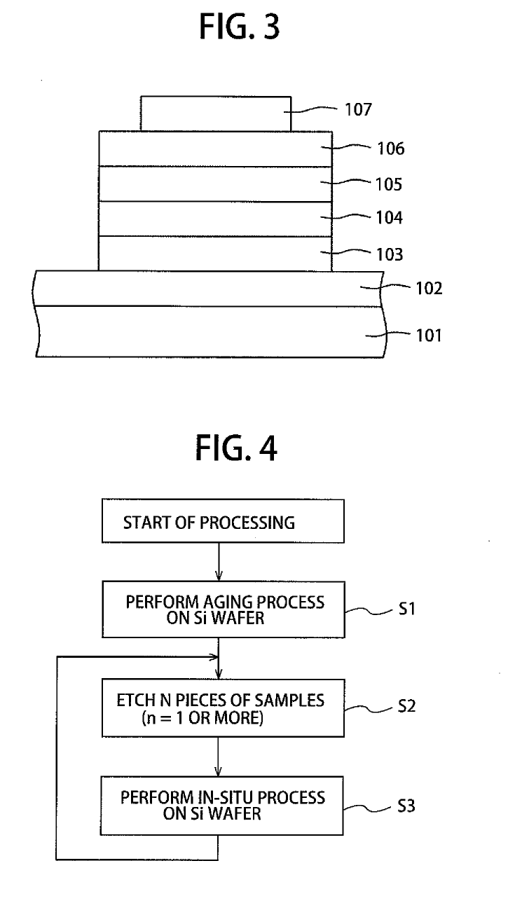

FIG. 3 shows the cross-sectional structure of the sample 12 that is used with the present embodiment and processed by the apparatus configured as described above. The sample 12 forms an electronic circuit pattern as it is obtained by overlaying a semiconductor Si substrate 101 sequentially with a base film 102, a barrier layer 103, a lower electrode layer 104, a ferroelectric layer 105, an upper electrode layer 106, and a hard mask 107.

The upper electrode layer 106 and lower electrode layer 104 may be made, for instance, of iridium oxide (IrOx), iridium-platinum alloy (IrPt), platinum oxide (PtOx), ruthenium (Ru), ruthenium oxide (RuOx), palladium (Pd), or palladium oxide (PdOx).

The ferroelectric layer 105 may be made, for instance, of PZT (lead zirconate titanate), PLZT (lead lanthanum zirconate titanate), BST (barium strontium titanate), or SBT (strontium bismuth tantalate) as mentioned earlier.

The barrier layer 103 may be made, for instance, of Ti, TiN, or TiAlON. The hard mask 107 may be made, for instance, of TiAlN or SiO₂. The sample used in the present embodiment is formed by the hard mask 107 made of TiAlN, the upper electrode layer 106 and lower electrode layer 104 made of Ir, the ferroelectric layer 105 made of PZT, and the barrier layer 103 made of TiAlON.

Etching process gases used for the sample are chlorine (Cl₂) and oxygen (O₂) for the upper electrode layer 106; boron trichloride (BCl₃) and argon (Ar) for the ferroelectric layer 105; chlorine (Cl₂), oxygen (O₂), and carbon tetrafluoride (CF₄) for the lower electrode layer 104; and boron trichloride (BCl₃), chlorine (Cl₂), and argon (Ar) for the barrier layer 103. A Faraday shield voltage of 1000 V or higher is applied during the use of the etching process gases. Further, a portion within the effective range of the Faraday shield is subjected to reaction product deposition control and removal while processing the film to be etched.

The structure of the sample is not limited to the above-described one. A thin film containing at least one etch-resistant material such as iron (Fe), nickel (Ni), platinum (Pt), manganese (Mn), iridium (Ir), gold (Au), tantalum (Ta), ruthenium (Ru), palladium (Pd), aluminum oxide, hafnium oxide, lead zirconate titanate, lead lanthanum zirconate titanate; barium strontium titanate, strontium bismuth tantalate, or titanium (Ti) may be formed on the sample.

Further, if the reaction product deposition on the inner wall of the bell jar does not exercise a significant influence, it is not always necessary to apply a voltage to the Faraday shield.

The sequence of sample processing performed in accordance with the present embodiment will now be described with reference to a flowchart of FIG. 4. First of all, step S1 is performed before the etching of a sample to transport a Si wafer and conduct plasma processing (aging) for the purpose of stabilizing the interior of the etching process room. Next, step S2 is performed to etch the sample with the Si wafer replaced with the sample, and then replace the sample with the Si wafer. After the sample is replaced with the Si wafer, step S3 is performed to conduct plasma processing (in-situ processing) with the Si wafer. Next, step S2 is performed again to etch the sample with the Si wafer replaced with the sample. The present embodiment assumes that the above-described process is repeated to make a successive processing evaluation and study the generation of foreign matter due to the flaking of a reaction product.

The present embodiment also assumes that etching is conducted during aging and in-situ processing while using 20 to 40 percent boron trichloride (BCl₃) and 60 to 80 percent chlorine (Cl₂) for etching the sample with bias high-frequency power set so as to provide a process pressure of 0.5 to 2.0 Pa, a Faraday shield voltage of 600 to 1500 V, and a wafer bias voltage of 300 V or higher.

The results of a successive processing evaluation made in accordance with the flowchart of FIG. 4 will now be described. Table 1 shows plasma processing conditions for aging and in-situ processing.

TABLE 1
Aging and in-situ processing conditions

| | | | | Source | Bias | |
|---|---|---|---|---|---|---|
| | | | | high- | high- | Faraday |
| | | | Process | frequency | frequency | shield |
| | BCl₃ | Cl₂ | pressure | power | power | voltage |
| Step | ml/min | | Pa | W | W | V |
| 1 | 20 | 80 | 0.5 | 1800 | 200 | 1500 |

Prior to successive processing performed under the above conditions, a foreign matter evaluation was made with a Si wafer to check for the flaking of a reaction product at the end of every 100 cycles of sample processing. The foreign matter evaluation was made by checking for foreign matter deposits having a size (particle diameter) of 0.20 μm or larger.

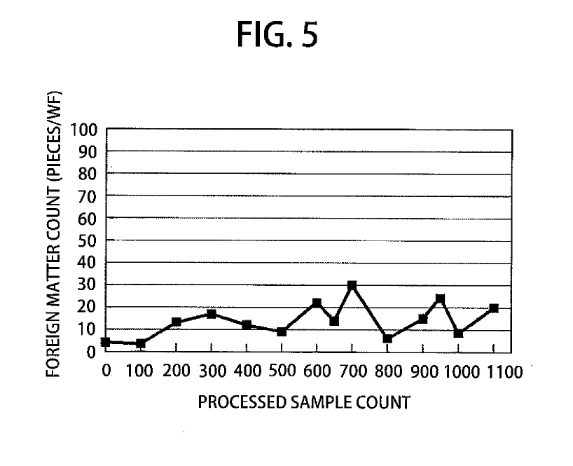

FIG. 5 shows the number of pieces of foreign matter that increased and decreased when successive processing was conducted. When the steps shown in FIG. 4 were followed to make a successive processing evaluation under the above-described processing conditions, up to 1100 samples could be successively processed without encountering a significant number of foreign matter deposits. This indicates that the method according to the present embodiment suppresses the flaking of a reaction product more successfully than the related art methods.

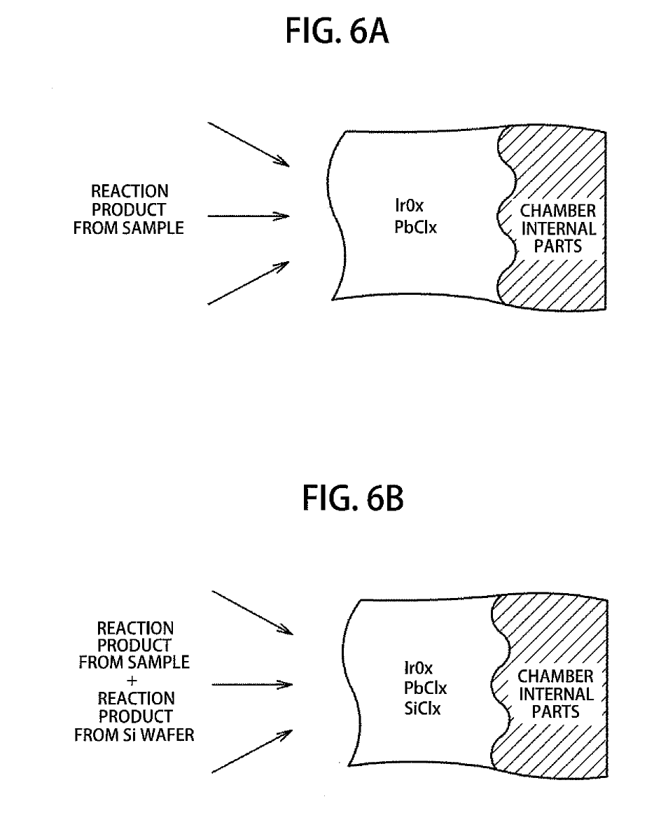

FIGS. 6A and 6B show the status of a reaction product that is deposited in the processing room during successive sample processing. When a sample containing an etch-resistant material is etched, a reaction product mainly composed of the etch-resistant material deposits on the inner wall of the processing room as shown in FIG. 6A. It is predicted that the amount of reaction product deposition will increase in proportion to the number of processed samples. However, when a related-art method is used, a reaction product mainly composed of an etch-resistant material is constantly deposited. It is therefore conceivable that the deposited reaction product would flake off and turn into foreign matter when several hundred samples are processed.

However, the method according to the present embodiment uses a Si wafer, which is a dummy substrate, during aging and in-situ processing. Therefore, the Si wafer is progressively etched so that a reaction product of SiClx is generated from the wafer. It is conceivable that the SiClx is generated between one sample processing operation and another and, as shown in FIG. 6B, deposited in the processing room in a reaction product state different from a state prevailing during the use of a related-art method. As the reaction product contains SiClx, it is firmer than during the use of a related-art method. As a result, the method according to the present embodiment ensures that the reaction product is stabilized and firmly deposited.

For such reaction product stabilization, it is preferred that in-situ processing be conducted after the sample is etched, or more specifically, immediately after the sample is etched. After the sample is etched, the temperature of the inner wall of the chamber is raised so that the reaction product can be thoroughly stabilized. Aging is conducted under conditions similar to those for in-situ processing. However, as aging is conducted before the sample is etched, it is conceivable that stabilization is not sufficiently achieved due to a low temperature of the chamber inner wall. It is believed that the same effect will be produced even when in-situ processing is conducted at the end of every n cycles of sample processing.

As described above, when a Si wafer etching process is applied to aging, which is conducted before the sample is processed, and to in-situ processing, which is conducted at the end of every cycle of sample processing, the present embodiment provides a plasma processing method that makes it possible to suppress the flaking of a reaction product deposited in the etching process room, reduce the level of foreign matter, and operate the apparatus consistently for a long period of time.

### Second Embodiment

A second embodiment of the present invention will now be described. However, the differences between the second embodiment and the first embodiment, which has been described above, will be mainly described while skipping the description of matters common to these two embodiments.

The second embodiment will be described with reference to a case where the inner wall of the chamber is heated before aging. As regards the hardware configuration, the second embodiment assumes that a heater is mounted on the outer circumference of the processor (chamber) 3 of the etching apparatus shown in FIG. 1. The etching apparatus was used to etch a sample by performing the steps shown in FIG. 4. The second embodiment differs from the first embodiment in that the processor 3 is heated by the heater (thermal aging) before the aging process on the Si wafer (step S1). The second embodiment assumes that the heater is set to a heating temperature of 100° C. However, the heating temperature setting is variable between 60° C. and 150° C.

The use of the above-described configuration makes it possible to reduce the amount of foreign matter deposited on the first and subsequent samples. In the first embodiment, the etching of a sample and the in-situ processing of a Si wafer are conducted alternately. In the second embodiment, on the other hand, three samples are successively etched after completion of thermal aging, and then the Si wafer is subjected to in-situ processing. When one batch, which is a unit of sample processing, includes more than 10 samples, the aging in step S1 and the in-situ processing in step S3 can be combined to reduce the amount of foreign matter deposited on the samples.

However, if one batch includes several samples or a smaller number of samples, the in-situ processing on the Si wafer can be omitted to perform only the thermal aging.

As described above, when a Si wafer is aged after heating the processor (chamber), the present embodiment provides a plasma processing method that suppresses the flaking of a reaction product deposited on a portion outside the effective range of the Faraday shield in the vacuum vessel and excels in mass production consistency. In addition, the present embodiment can further reduce the amount of foreign matter deposited on a sample by combining the aging process (thermal aging process) on a Si wafer, which is conducted after heating the processor, with the in-situ process on the Si wafer. Further, if a small number of samples are to be processed, the in-situ process on the Si wafer can be omitted to perform only the thermal aging process. It means that the amount of deposited foreign matter can be reduced by performing a simple procedure.

It should be understood by those skilled in the art that various modifications, combinations, sub-combinations, and alterations may occur depending on design requirements and other factors insofar as they are within the scope of the appended claims or the equivalents thereof.

What is claimed is:

1. A plasma processing method comprising:
a plasma processing step of plasma-processing a sample having a thin film formed with an etch-resistant material within a chamber; and
a stabilization step of stabilizing a film that is deposited on the inner wall of the chamber during the plasma processing step.

2. The plasma processing method according to claim 1, wherein the etch-resistant material is at least one of iron (Fe), nickel (Ni), platinum (Pt), manganese (Mn), iridium (Ir), gold (Au), tantalum (Ta), ruthenium (Ru), palladium (Pd), aluminum oxide, hafnium oxide, lead zirconate titanate, lead lanthanum zirconate titanate, barium strontium titanate, strontium bismuth tantalate, and titanium (Ti).

3. The plasma processing method according to claim 1, wherein the stabilization step comprises the step of etching a Si wafer in the chamber with plasma generated from a mixed gas containing boron trichloride and chlorine.

4. The plasma processing method according to claim 3, wherein the mixed gas contains 20 to 40 percent boron trichloride and 60 to 80 percent chlorine.

5. A plasma processing method that plasma-processes a sample having a layer of an etch-resistant material by using a plasma processing apparatus having a discharger and a processor, the plasma processing method comprising:
a first step of performing an aging process that is to be performed before etching the sample;
a second step of performing etching by plasma-processing the layer of an etch-resistant material formed on the sample;
a third step of stabilizing a reaction product deposited on the inner wall of a chamber forming the processor after the second step; and
an additional step of repeating the second step and the third step.

6. The plasma processing method according to claim 5, wherein the third step comprises the step of etching a Si wafer in the chamber by using plasma generated from a mixed gas containing boron trichloride and chlorine.

7. The plasma processing method according to claim 5, wherein the third step is performed after a plurality of samples are etched in the second step.

8. The plasma processing method according to claim 5, wherein the plasma processing apparatus includes a Faraday shield which is positioned in the upper part of a bell jar forming the discharger; and
wherein the third step is performed while a voltage is applied to the Faraday shield.

9. A plasma processing method that plasma-processes a sample having a layer of an etch-resistant material by using a plasma processing apparatus having a discharger and a processor, the plasma processing method comprising:
a first step of heating the inner wall of a chamber which forms the processor, and then stabilizing a reaction product deposited on the inner wall of the chamber by performing an aging process that is to be performed before etching the sample; and
a second step of performing etching by plasma-processing the layer of an etch-resistant material formed on the sample.

10. The plasma processing method according to claim 9, wherein the first step comprises the step of etching a Si wafer in the chamber by using plasma generated from a boron trichloride gas and a chlorine gas.

11. The plasma processing method according to claim 9, further comprising:
a third step of stabilizing a reaction product deposited on the inner wall of a chamber forming the processor after completion of the second step.

12. The plasma processing method according to claim 11, further comprising:
an additional step of repeating the second step and the third step.
